(19) United States
(12) Patent Application Publication
(10) Pub. No.: US 2021/0287086 A1
(43) Pub. Date: Sep. 16, 2021

(54) Wafer testing machine and method for training artificial intelligence model to test wafer

(71) Applicant: REALTEK SEMICONDUCTOR CORPORATION, HSINCHU (TW)

(72) Inventors: YIN-PING CHERN, Hsinchu (TW); PO-LIN CHEN, Hsinchu (TW); CHUN-YI KUO, Hsinchu (TW); YING-YEN CHEN, Hsinchu (TW); CHUN-TENG CHEN, Hsinchu (TW)

(21) Appl. No.: 17/190,458

(22) Filed: Mar. 3, 2021

(30) Foreign Application Priority Data
Mar. 10, 2020 (TW) 109107898

(51) Int. Cl. G06N 3/08; G06N 3/04; G01R 31/28

(52) U.S. Cl. CPC G06N 3/08; G01R 31/2831; G06N 3/0454

(57) ABSTRACT

A wafer testing machine and a method for training an artificial intelligence (AI) model to test wafers are provided. The wafer contains multiple dies. The method includes the following steps of: determining a target die from the dies; selecting multiple reference dies close to the target die based on the target die and a preset range; generating a main training data which includes a measured value of the target die and the measured value of each reference die; generating an auxiliary training data which indicates whether each reference die is a passed die or a failed die; and training the AI model using the main training data and the auxiliary training data.

### BACKGROUND OF THE INVENTION

### 1. Field of the Invention

The present invention generally relates to semiconductor manufacturing, and, more particularly, to wafer testing.

### 2. Description of Related Art

In the tests for complementary metal oxide semiconductor (CMOS) circuits, the Supply Current Quiescent (IDDQ) is a commonly used characteristic for the detection of faults in a die. For the dies which function properly, the current variation between different sets of test patterns is very small, that is to say, the measured IDDQ values in different sets of test patterns should be close to the average IDDQ value of a certain die. In the conventional art, whether a die is faulty is determined using a fixed IDDQ threshold.

However, because for CMOS circuits a major component of the IDDQ value is the transistors' leakage currents which fluctuate as a result of process variations, IDDQ values vary from chip to chip on the same wafer due to the process variations. In other words, using a fixed IDDQ threshold in the IDDQ test in the conventional art is not practical.

### SUMMARY OF THE INVENTION

In view of the issues of the prior art, an object of the present invention is to provide a wafer testing machine and a method of training artificial intelligence (AI) models to test wafers, so as to make an improvement to the prior art.

A wafer testing machine is provided. The wafer testing machine is used for testing a wafer containing multiple dies and includes measurement equipment, a database, a storage circuit, and a computing circuit. The measurement equipment is used for measuring the dies to generate a measured value for each die. The database is used for storing the measured values. The storage circuit is used for storing multiple program instructions or program codes and storing an AI model configured to test the wafer. The computing circuit is coupled to the storage circuit and the database and configured to execute the program instructions or program codes to perform the following steps to train the AI model: determining a target die from the dies; selecting, based on the target die and a predetermined range, multiple reference dies neighboring the target die; generating a main training data including the measured value of the target die and the measured values of the reference dies; generating an auxiliary training data indicating whether each reference die is a passed die or a failed die; and training the AI model using the main training data and the auxiliary training data.

A method of training an AI model to test a wafer is provided. The wafer contains multiple dies. The method includes the following steps: determining a target die from the dies; selecting, based on the target die and a predetermined range, multiple reference dies neighboring the target die; generating a main training data including a measured value of the target die and the measured values of the reference dies; generating an auxiliary training data indicating whether each reference die is a passed die or a failed die; and training the AI model using the main training data and the auxiliary training data.

According to this invention, the wafer testing machine and the method of training AI models to test wafers take the dies surrounding or neighboring the target die into consideration and use the AI models to facilitate the determination of whether the target die is faulty. In comparison with the conventional art, this invention can find the faulty die(s) more accurately and quickly.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is a functional block diagram of the wafer testing machine according to an embodiment of this disclosure.

FIG. 2 is a functional block diagram of the AI model and the training data according to an embodiment of this disclosure.

FIG. 3 is a flowchart of a method of training an AI model to test wafers according to an embodiment of this disclosure.

FIG. 4 shows a wafer containing multiple dies.

FIG. 5 is a schematic diagram of the internal architecture of the AI model of FIG. 2.

FIG. 6 is a flowchart of a method of testing wafers using AI models according to this disclosure.

FIG. 7 is a flowchart of a method of training an AI model to test wafers according to another embodiment of this disclosure.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes a wafer testing machine and a method for training an AI model to test wafers. On account of that some or all elements of the wafer testing machine could be known, the detail of such elements is omitted provided that such detail has little to do with the features of this disclosure, and that this omission nowhere dissatisfies the specification and enablement requirements. Some or all of the processes of the method of training an AI model to test wafers may be implemented by software and/or firmware, and can be performed by the wafer testing machine or its equivalent. A person having ordinary skill in the art can choose components or steps equivalent to those described in this specification to carry out the present invention, which means that the scope of this invention is not limited to the embodiments in the specification.

Although the terms “first,” “second,” etc., may be used herein to describe various elements, these elements should not be limited by these terms. Rather, these terms are only used to distinguish one element from another. For example, a first element could be termed a second element, and, similarly, a second element could be termed a first element, without departing from the scope of the embodiments.

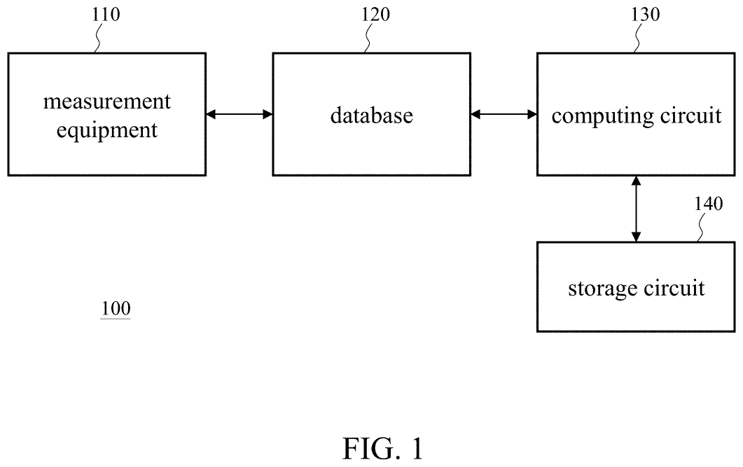

FIG. 1 is a functional block diagram of the wafer testing machine according to this disclosure. The wafer testing machine 100 includes measurement equipment 110, a database 120, a computing circuit 130 and a storage circuit 140. A wafer contains multiple dies. Before being tested by the wafer testing machine 100, each die on the wafer has been tested by other testing machines for the determination of being a passed die or a failed die. A passed die is a die that functions normally, whereas a failed die is a die that cannot function normally. The measurement equipment 110 measures the target characteristic(s) of the passed die, and a measured value for each passed die is obtained. In some embodiments, the target characteristic may be the aforementioned IDDQ, in which case the measured value is the IDDQ value. In other embodiments, the target characteristic can be the ring oscillator frequency, the thermal meter value or the voltage sensor value, with the corresponding measured value being the frequency, temperature or voltage, respectively. Similar to the IDDQ, the ring oscillator frequency, thermal meter value or voltage sensor value can also be used as the characteristic for the determination of whether a die is faulty. People having ordinary skill in the art know how to measure the IDDQ value, ring oscillator frequency, thermal meter value and voltage sensor value of the die, so the structure and operation details of the measurement equipment 110 are omitted for brevity. The following descriptions are illustrated by examples in which the IDDQ is used as the target characteristic, but this disclosure is not limited to the IDDQ.

The database 120 stores the measured values that are measured or outputted by the measurement equipment 110 and stores data indicative of whether the dies are passed or failed dies. The storage circuit 140 can be implemented with a volatile memory and/or a non-volatile memory, and the storage circuit 140 stores multiple program instructions or program codes as well as an AI model that is utilized to test the wafer. The computing circuit 130 may be a circuit or electronic component with program execution capability, such as a central processing unit (CPU), a microprocessor, a micro processing unit or a graphics processing unit (GPU). The computing circuit 130 executes the program instructions or program codes to train the AI model. Once the training of the AI model is completed, the wafer testing machine 100 can use the AI model to determine whether the passed dies are faulty.

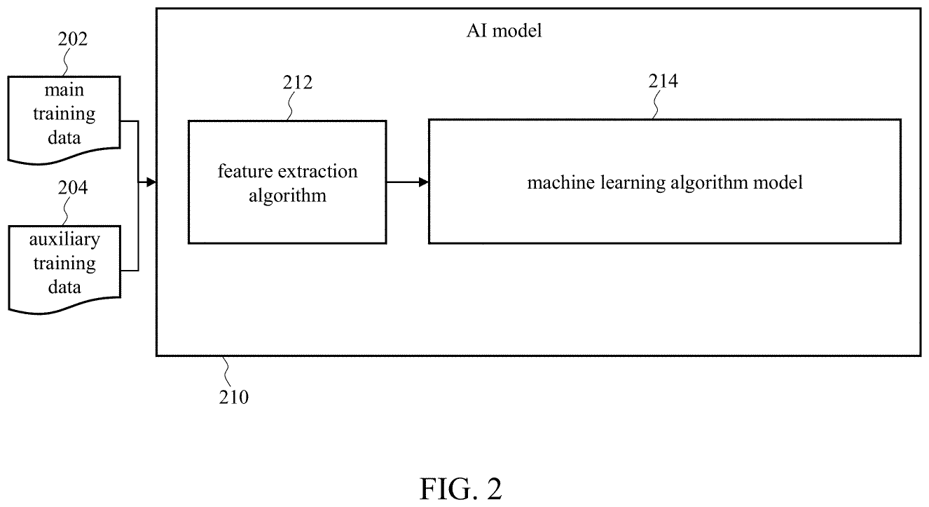

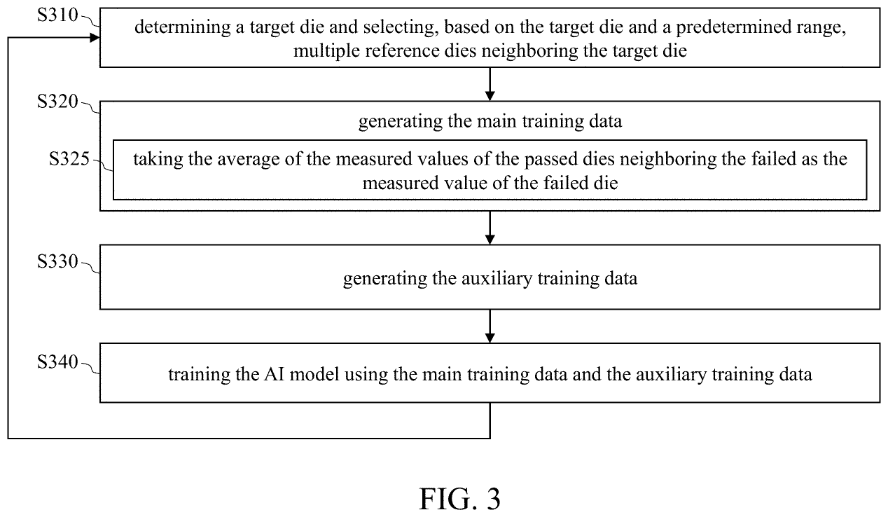

FIG. 2 is a functional block diagram of the AI model and the training data according to an embodiment of this disclosure. FIG. 3 is a flowchart of a method of training an AI model to test wafers according to an embodiment of this disclosure. Reference is made to FIG. 1 to FIG. 3 for the following description.

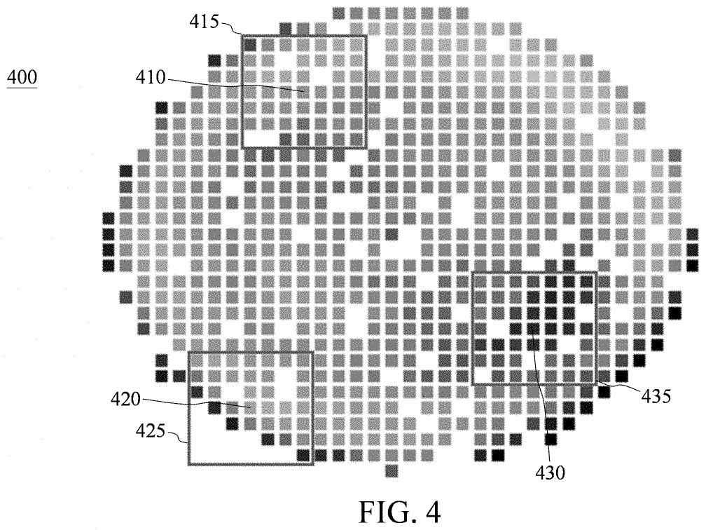

First, the computing circuit 130 determines a target die from multiple dies on a wafer, and then selects, based on the target die and a predetermined range, multiple reference dies neighboring the target die (step S310). Reference is made to FIG. 4, which shows that a wafer 400 contains multiple dies. The dies 410, 420 and 430 can be the aforementioned target die, and the regions 415, 425 and 435 can be the aforementioned predetermined range. In the illustrative example of FIG. 4, the predetermined range is a 7×7 rectangle (including at most 49 dies), and the target die is at the center of the predetermined range. However, the predetermined range of this disclosure is not limited to a 7×7 rectangle but can also be other sizes and shapes, such as a 5×5 rectangle or a 3×10 rectangle. Furthermore, the target die is not limited to being at the center of the predetermined range.

In FIG. 4, each dot filled with a grayscale color (except the white color) represents a die, and the blank area (including but not limited to white dots) represents either absence of a die or a failed die. For example, the region 415 includes four failed dies and 45 passed dies, the region 425, which is at the edge of the wafer 400, includes three failed dies and 33 passed dies, and the region 435 includes five failed dies and 44 passed dies. The grayscale value may represent the magnitude of the measured value for the target characteristic of the die. For example, the grayscale value may be proportional to the measured value.

After step S310 is completed (i.e., after the target die and multiple reference dies are determined), the computing circuit 130 generates the main training data 202 based on the measured values of the target die and the reference dies (step S320), that is, the main training data 202 includes the measured value of the target die and the measured values of the reference dies. For example, the main training data 202 corresponding to the region 415 can be expressed as follows (where I_{(x,y)} is the measured value of the target die, and x and y are integers):

$$[ \begin{matrix}{I}_{( x - 3 , y + 3 )} & {I}_{( x - 2 , y + 3 )} & … & {I}_{( x + 2 , y + 3 )} & {I}_{( x + 3 , y + 3 )} \\ {I}_{( x - 3 , y + 2 )} & {I}_{( x - 2 , y + 2 )} & … & {I}_{( x + 2 , y + 2 )} & {I}_{( x + 3 , y + 2 )} \\ … & … & {I}_{( x , y )} & … & … \\ {I}_{( x - 3 , y - 2 )} & {I}_{( x - 2 , y - 2 )} & … & {I}_{( x + 2 , y - 2 )} & {I}_{( x + 3 , y - 2 )} \\ {I}_{( x - 3 , y - 3 )} & {I}_{( x - 2 , y - 3 )} & … & {I}_{( x + 2 , y - 3 )} & {I}_{( x + 3 , y - 3 )}\end{matrix} ]$$

Since there is no measured value for failed dies, step S320 further includes a sub-step of taking the average of the measured values of the neighboring passed dies as the missing measured value (step S325). In some embodiments, the computing circuit 130 calculates the average value of the eight measured values surrounding the missing measured value and uses the average value as the missing measured value. For example,

$${I}_{( p , q )} = \frac{1}{8} ( {I}_{( p - 1 , q - 1 )} + {I}_{( p , q - 1 )} + {I}_{( p + 1 , q - 1 )} + {I}_{( p - 1 , q )} + {I}_{( p + 1 , q )} + {I}_{( p - 1 , q + 1 )} + {I}_{( p , q + 1 )} + {I}_{( p + 1 , q + 1 )} ) ,$$

where I_{(p,q)} is the missing measured value (p and q are integers, denoting the coordinates of the failed die). When, however, the number of the passed dies neighboring the failed die is smaller than eight, the average value of the measured values of the neighboring passed dies is calculated. It should be noted that because the target die is the target to predict, the computing circuit 130 treats the measured value of the target die as a missing measured value (i.e., neglecting the measured value of the target die) and uses the average of the measured values of the reference dies surrounding the target die as the measured value of the target die.

Next, the computing circuit 130 generates the auxiliary training data 204 according to whether the target die and the reference dies are passed dies (step S330). The auxiliary training data 204 indicates whether the reference dies are passed or failed dies. For example, the auxiliary training data 204 corresponding to regions 415, 425 and 435 are as follows (“1” being indicative of the failed die):

$$415 \text{:} [ \begin{matrix}0 & 0 & 0 & 0 & 0 & 0 & 0 \\ 0 & 0 & 1 & 0 & 0 & 0 & 0 \\ 0 & 0 & 0 & 0 & 1 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 1 & 1 & 0 & 0 & 0 & 0 & 0\end{matrix} ]$$

$$425 \text{:} [ \begin{matrix}0 & 0 & 0 & 0 & 0 & 0 & 0 \\ 0 & 0 & 0 & 0 & 0 & 1 & 0 \\ 0 & 0 & 1 & 0 & 0 & 1 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0\end{matrix} ]$$

$$435 \text{:} [ \begin{matrix}0 & 0 & 0 & 0 & 0 & 0 & 0 \\ 0 & 0 & 0 & 0 & 0 & 0 & 0 \\ 0 & 0 & 0 & 0 & 0 & 0 & 1 \\ 0 & 1 & 0 & 0 & 0 & 0 & 0 \\ 0 & 0 & 0 & 0 & 0 & 1 & 0 \\ 0 & 0 & 0 & 1 & 0 & 0 & 0 \\ 1 & 0 & 0 & 0 & 0 & 0 & 0\end{matrix} ]$$

After the main training data 202 and the auxiliary training data 204 are generated, the computing circuit 130 uses the main training data 202 and the auxiliary training data 204 to train the AI model 210 (step S340), that is, the computing circuit 130 inputs the main training data 202 and the auxiliary training data 204 into the AI model 210. The AI model 210 includes a feature extraction algorithm 212 and a machine learning algorithm model 214.

The feature extraction algorithm 212 is used for selecting a representative feature set in the main training data 202 and the auxiliary training data 204. In addition to reducing over-fitting, the feature extraction algorithm 212 can also reduce the complexity of the mathematical model. The paper “L. C. Molina, L. Belanche, A. Nebot (2002). Feature selection algorithms: a survey and experimental evaluation. 2002 IEEE International Conference on Data Mining, 2002. Proceedings” discusses several examples of the feature extraction algorithm. People having ordinary skill in the art can refer to this paper to implement the feature extraction algorithm 212, so the details are omitted for brevity.

The machine learning algorithm model 214 is used for processing the feature set generated by the feature extraction algorithm 212. The machine learning algorithm used in this disclosure may include the Bayesian Ridge Regression algorithm, the Gaussian Process Regression algorithm, the scalable variational Gaussian process algorithm or the Convolutional Neural Network (CNN) algorithm. The CNN algorithm includes the feature extraction function; therefore, the feature extraction algorithm 212 can be omitted (i.e., the feature extraction algorithm 212 is integrated into the CNN algorithm) when the algorithm that the machine learning algorithm model 214 adopts is the CNN algorithm.

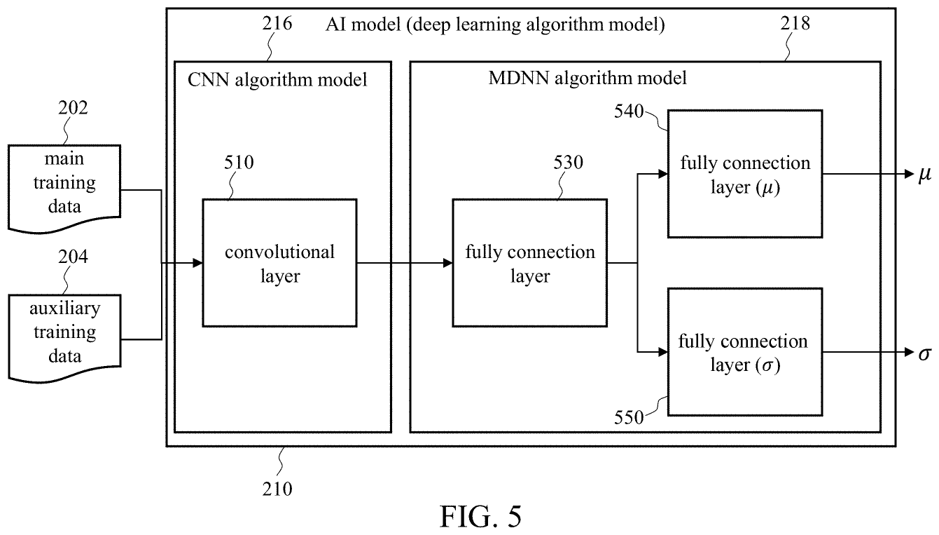

FIG. 5 is a schematic diagram of one of the internal architectures of the AI model 210 (e.g., the deep learning algorithm model) of FIG. 2. In the embodiment of FIG. 5, the AI model 210 is implemented with a deep learning algorithm model which includes a CNN algorithm model 216 and a Mixture Density Neural Network (MDNN) algorithm model 218. The number of filters in each convolutional layer of the CNN algorithm model 216 can be set arbitrarily. In comparison with FIG. 2, the embodiment of FIG. 5 does not include the feature extraction algorithm 212 of FIG. 2 because the deep learning algorithm model of FIG. 5 adopts the CNN algorithm model 216.

The MDNN algorithm model 218 is used for predicting the complete probability distribution. The general architecture of the MDNN algorithm is the same as the general Multiple Layer Perceptron, but, in addition to the fully connection layer, the MDNN algorithm is also connected at the end to three independent layers: “Alpha (α),” “Mu (μ)” and “Sigma (σ).” In this disclosure, “Alpha (α)” can be neglected. The loss function used in the MDNN algorithm in this disclosure is shown in the following equation. People having ordinary skill in the art can refer to the document “Bishop, Christopher M. (1994). Mixture density networks. Technical Report. Aston University, Birmingham” and the loss function below to implement the MDNN algorithm model 218.

$$f ( x \vert μ , {σ}^{2} ) = \frac{1}{\sqrt{2 π} σ} exp \{ - \frac{{\vert x - μ \vert}^{2}}{2 {σ}^{2}} \}$$

$${argmax}_{θ} L ( θ \vert x ∈ [ {x}_{i} , {x}_{i} + h ] ) = {argmax}_{θ} \frac{1}{h} L ( θ \vert x ∈ [ {x}_{i} , {x}_{i} + h ] ) = {argmax}_{θ} \frac{1}{h} Pr ( {x}_{i} \leq x \leq {x}_{i} + h \vert θ ) = {argmax}_{θ} \frac{1}{h} {\int }_{{x}_{i}}^{{x}_{i} + h} f ( x \vert θ ) dx$$

$${lim}_{h \to 0} \frac{1}{h} {\int }_{{x}_{i}}^{{x}_{i} + h} f ( x \vert θ ) dx = f ( {x}_{i} \vert θ )$$

$${argmax}_{θ} L ( θ \vert {x}_{i} ) = {argmax}_{θ} f ( {x}_{i} \vert θ )$$

The main training data 202 and auxiliary training data 204 are fed into the convolutional layer 510 of the CNN algorithm model 216 of the AI model 210, and are then expanded into a one-dimensional tensor after being processed by the convolutional layer 510, followed by the one-dimensional tensor being inputted to the fully connection layer 530 of the MDNN algorithm model 218 and then divided into two independent fully connection layers: a fully connection layer (μ) 540 and a fully connection layer (σ) 550. In some embodiments, if the main training data 202 and the auxiliary training data 204 are each an N×N matrix (N is a positive integer), the convolutional layer 510 includes 12 convolution kernels, and its outputted feature map contains 12 N′×N′ matrices (N′<N). As a result, the dimension of the one-dimensional tensor is 12×N′×N′, the dimension of the fully connection layer 530 is (12×N′×N′)×512, and the dimensions of the fully connection layer (μ) 540 and the fully connection layer (σ) 550 are both 512×256. People having ordinary skill in the art can implement the AI model 210 based on the embodiments discussed above.

Reference is made to FIG. 3. After step S340 is completed, the computing circuit 130 selects the next target die on the current wafer and executes steps S310 to S340 again, until all the dies on the current wafer have been used as the target die. After all the dies on the current wafer have been selected as the target die, the computing circuit 130 may select the measured values of the next wafer from the database 120 to continue to perform steps S310 to S340.

During the training process, the AI model 210 uses the measured value of the target die as the target average value to continually adjust the parameters. After training, the AI model 210 can predict the range of the threshold for the measured value of the target die, that is: the average μ plus/minus (±) the setting coefficient times (×) the standard deviation a, where the setting coefficient is a parameter for adjusting the range of the threshold. When the setting coefficient is one, μ−σ is the lower threshold, and μ+σ is the upper threshold, in which case, if the measured value of the target die is greater than or equal to and less than or equal to μ+σ, the target die is determined a die which is not faulty.

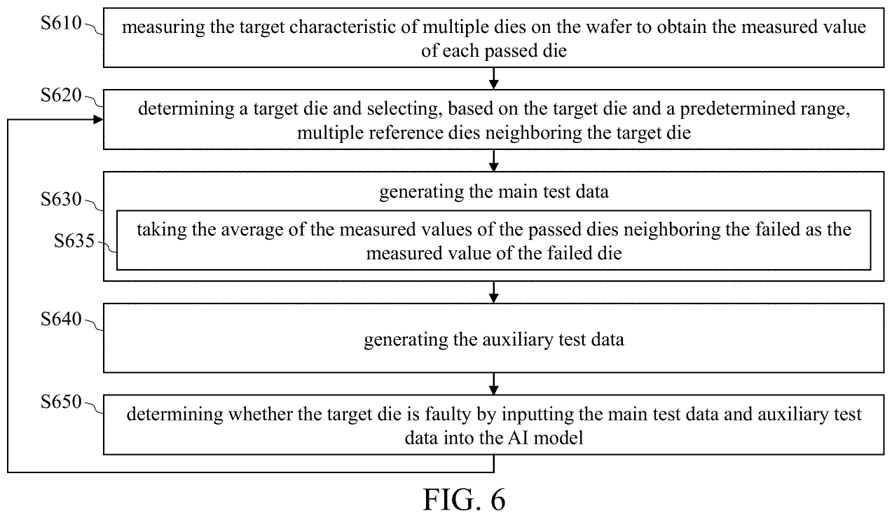

Reference is made to FIG. 6, which is a flowchart of the method of testing wafers using the AI model according to this disclosure. First, the measurement equipment 110 measures the target characteristic of multiple dies on the wafer to obtain the measured value of each passed die (step S610). Next, the computing circuit 130 determines a target die, and selects, based on the target die and a predetermined range, multiple reference dies neighboring the target die (step S620). Step S620 is similar to step S310, so the details are omitted for brevity. Then, the computing circuit 130 generates the main test data (step S630), and the step S630 includes the sub-step S635. The format of the main test data is the same as the main training data 202. Since step S630 and step S635 are similar to step S320 and step S325, respectively, the details are thus omitted for brevity. Next, the computing circuit 130 generates the auxiliary test data (step S640), and the format of the auxiliary test data is the same as the auxiliary training data 204. Since step S640 is similar to step S330, the details are omitted for brevity. Next, the computing circuit 130 inputs the main test data and auxiliary test data into the trained AI model 210 to determine whether the target die is faulty (step S650). The AI model 210 predicts the range of the threshold for the measured value of the target die based on the measured values of the reference dies, and then determines whether the measured value of the target die falls within the range of the threshold. If so, the AI model 210 (or the computing circuit 130) determines that the target die is not faulty; if not, the AI model 210 (or the computing circuit 130) determines that the target die is faulty.

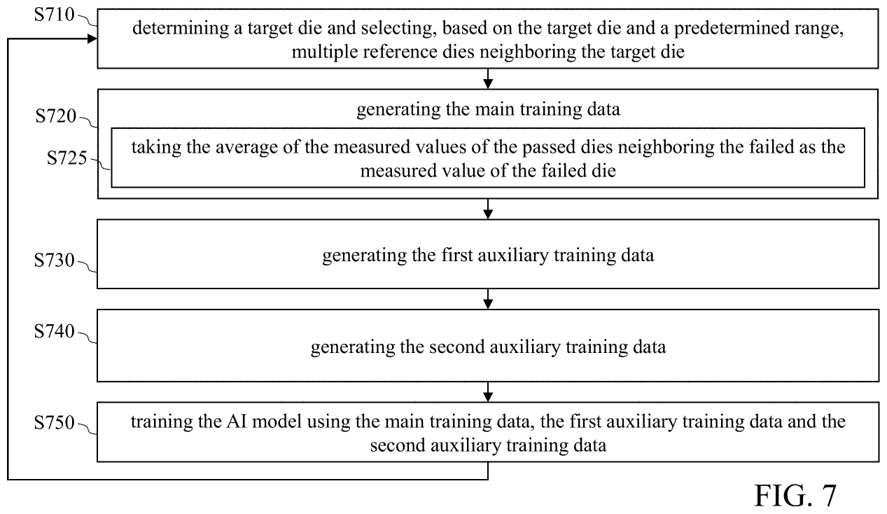

FIG. 7 is a flowchart of a method of training an AI model to test wafers according to another embodiment of this disclosure. Steps S710, S720, S725 and S730 are similar to steps S310, S320, S325 and S330 in FIG. 3, respectively, so the details are thus omitted for brevity. The first auxiliary training data in step S730 is the auxiliary training data in step S330. In the embodiment of FIG. 7, the computing circuit 130 further generates the second auxiliary training data (step S740), which indicate whether the target die and/or the reference dies is/are located at the edge of the wafer, or whether the reference dies exist. For example (reference is made to FIG. 4), because the region 415 and the region 435 both contain N×N dies (passed or failed), the second auxiliary training data corresponding to the region 415 and the region 435 can be expressed as (“0” means that there is a die at the corresponding location):

$$415 \text{:} [ \begin{matrix}0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0\end{matrix} ]$$

$$435 \text{:} [ \begin{matrix}0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0\end{matrix} ]$$

For another example, because the region 425 covers the inside and the outside of the wafer 400, the second auxiliary training data corresponding to the region 425 can be expressed as (“0” means that there is a die at the corresponding location, and “1” means that there is no die at the corresponding location):

$$425 \text{:} [ \begin{matrix}0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 1 & 0 & 0 & 0 & 0 & 0 & 0 \\ 1 & 1 & 0 & 0 & 0 & 0 & 0 \\ 1 & 1 & 1 & 1 & 0 & 0 & 0 \\ 1 & 1 & 1 & 1 & 1 & 1 & 0\end{matrix} ]$$

As shown in the above example, when the target die and/or the reference dies are located at the edge of the wafer (such as the region 425), the second auxiliary training data contain two values (“0” and “1”). On the other hand, when the target die and/or the reference dies are not located at the edge of the wafer (such as the region 415 and the region 435), the second auxiliary training data contain only one value (“0”).

After the main training data, the first auxiliary training data and the second auxiliary training data are generated, the computing circuit 130 trains the AI model 210 using the main training data, the first auxiliary training data and the second auxiliary training data (step S750).

In another embodiment, the auxiliary training data of FIG. 3 may indicate whether the reference dies are passed or failed dies and/or whether the target die and/or the reference dies are located at the edge of the wafer. For example (reference is made to FIG. 4), the auxiliary training data corresponding to the region 415 and the region 435 can be expressed as (“0” means that the die at the corresponding position is a passed die, and “1” means that the die at the corresponding position is a failed die or that there is no die at the corresponding position):

$$415 \text{:} [ \begin{matrix}0 & 0 & 0 & 0 & 0 & 0 & 0 \\ 0 & 0 & 1 & 0 & 0 & 0 & 0 \\ 0 & 0 & 0 & 0 & 1 & 0 & 0 \\ 0 & 0 & 0 & 0 & 0 & 0 & 0 \\ 0 & 0 & 0 & 0 & 0 & 0 & 0 \\ 0 & 0 & 0 & 0 & 0 & 0 & 0 \\ 1 & 1 & 0 & 0 & 0 & 0 & 0\end{matrix} ]$$

$$435 \text{:} [ \begin{matrix}0 & 0 & 0 & 0 & 0 & 0 & 0 \\ 0 & 0 & 0 & 0 & 0 & 0 & 0 \\ 0 & 0 & 0 & 0 & 0 & 0 & 1 \\ 0 & 1 & 0 & 0 & 0 & 0 & 0 \\ 0 & 0 & 0 & 0 & 0 & 1 & 0 \\ 0 & 0 & 0 & 1 & 0 & 0 & 0 \\ 1 & 0 & 0 & 0 & 0 & 0 & 0\end{matrix} ]$$

For another example, the auxiliary training data corresponding to the region 425 can be expressed as:

$$425 \text{:} [ \begin{matrix}0 & 0 & 0 & 0 & 0 & 0 & 0 \\ 0 & 0 & 0 & 0 & 0 & 1 & 0 \\ 0 & 0 & 1 & 0 & 0 & 1 & 0 \\ 1 & 0 & 0 & 0 & 0 & 0 & 0 \\ 1 & 1 & 0 & 0 & 0 & 0 & 0 \\ 1 & 1 & 1 & 1 & 0 & 0 & 0 \\ 1 & 1 & 1 & 1 & 1 & 1 & 0\end{matrix} ]$$

As shown in the above example, in this embodiment, the location where there is no die is treated as or deemed a failed die. In other words, the auxiliary training data of this embodiment is equivalent to the union of the first auxiliary training data and the second auxiliary training data in the embodiment of FIG. 7.

Because neighboring dies on a wafer are subjected to similar process conditions, the threshold for the measured value associated with the target characteristic can be more accurately determined based on the dies within a local range instead of on all the dies on the entire wafer. Therefore, the probability of misjudgment is reduced. For example, the IDDQ value of the die 410 in FIG. 4 may not exceed the fixed IDDQ threshold used in the conventional art, but it may probably be out of the threshold range (i.e., the average μ plus/minus (±) the setting coefficient times (×) the standard deviation a) when the die 410 is compared with its neighboring dies (i.e., the reference dies in the region 415). Experiments show that the die 410 of this kind (the IDDQ value of which does not exceed the fixed IDDQ threshold used in the prior art but falls beyond the threshold range that the AI model of this disclosure determines) is very likely to be a faulty die, but the test method of the conventional art cannot find that the die 410 is a faulty die.

As illustrated in the previous examples, the main training data and auxiliary training data are in the form of a matrix or array, and the relative positions of the elements in the matrix or array reflect the relative positions on the wafer of the target die and the reference dies. In other words, the elements of the matrix or array are arranged in accordance with the positions of the target die and reference dies on the wafer. As a result, the wafer can be treated as an image, with each pixel of which representing a die, and the elements of the main training data and auxiliary training data can be analogous to the pixel values of the image.

In some embodiments, the main training data and auxiliary training data correspond to a certain combination of a voltage and a temperature, that is, the main training data and auxiliary training data are measured at a certain voltage-temperature combination. However, in other embodiments, the main training data and auxiliary training data may correspond to multiple combinations of various voltages and temperatures since the measured values of the dies and whether the dies are passed or failed dies are dependent on voltage and temperature. For example, if there are four voltage-temperature combinations (e.g., two temperatures versus two voltages), then in the embodiments of FIG. 3 and FIG. 7, the training data actually includes four combinations of the main training data and the auxiliary training data, with each combination corresponding to a certain voltage-temperature combination.

To sum up, this disclosure takes the dies around the target die into consideration and uses the AI model to facilitate the determination of whether the target die is faulty. Therefore, the faulty die(s) can be found or identified more accurately and quickly. Furthermore, experiments show that more accurate results are obtained using the AI model that has been trained with both the main training data and auxiliary training data than using the AI model that has been trained with the main training data only.

Since a person having ordinary skill in the art can appreciate the implementation detail and the modification thereto of the present method invention through the disclosure of the device invention, repeated and redundant description is thus omitted. Please note that there is no step sequence limitation for the method inventions as long as the execution of each step is applicable. Furthermore, the shape, size, and ratio of any element and the step sequence of any flowchart in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A wafer testing machine, used for testing a wafer containing a plurality of dies, comprising:
measurement equipment, used for measuring the dies to generate a measured value for each die;
a database, used for storing the measured values;
a storage circuit, used for storing a plurality of program instructions or program codes and storing an AI model configured to test the wafer; and
a computing circuit, coupled to the storage circuit and the database and configured to execute the program instructions or program codes to perform following steps to train the AI model:
determining a target die from the dies;
selecting, based on the target die and a predetermined range, a plurality of reference dies neighboring the target die;
generating a main training data including the measured value of the target die and the measured values of the reference dies;
generating an auxiliary training data indicating whether each reference die is a passed die or a failed die; and
training the AI model using the main training data and the auxiliary training data.

2. The wafer testing machine of claim 1, wherein the AI model comprises a feature extraction algorithm and a machine learning algorithm model.

3. The wafer testing machine of claim 2, wherein the machine learning algorithm model is selected from a group consisting of Bayesian Ridge Regression algorithm, Gaussian Process Regression algorithm and scalable variational Gaussian process algorithm.

4. The wafer testing machine of claim 1, wherein the AI model is a deep learning algorithm model, and the deep learning algorithm model comprises a Convolutional Neural Network (CNN) algorithm model and a Mixture Density Neural Network (MDNN) algorithm model.

5. The wafer testing machine of claim 1, wherein the auxiliary training data is a first auxiliary training data, and the computing circuit further performs following steps:
generating a second auxiliary training data indicating whether at least one of the target die and the reference dies exists; and
training the AI model using the second auxiliary training data together with the main training data and the first auxiliary training data.

6. The wafer testing machine of claim 1, wherein the auxiliary training data further indicates whether the reference dies exist.

7. The wafer testing machine of claim 1, wherein the main training data and the auxiliary training data correspond to a combination of a temperature and a voltage.

8. The wafer testing machine of claim 1, wherein the main training data and the auxiliary training data correspond to a plurality of combinations of a plurality of temperatures and a plurality of voltages.

9. The wafer testing machine of claim 1, wherein the main training data and the auxiliary training data are a matrix or an array, and relative positions of a plurality of elements in the matrix or the array correspond to relative positions on the wafer of the target die and the reference dies.

10. A method of training an AI model to test a wafer containing a plurality of dies, comprising:
determining a target die from the dies;
selecting, based on the target die and a predetermined range, a plurality of reference dies neighboring the target die;
generating a main training data including a measured value of the target die and the measured values of the reference dies;
generating an auxiliary training data indicating whether each reference die is a passed die or a failed die; and
training the AI model using the main training data and the auxiliary training data.

11. The method of claim 10, wherein the AI model comprises a feature extraction algorithm and a machine learning algorithm model.

12. The method of claim 11, wherein the machine learning algorithm model is selected from a group consisting of Bayesian Ridge Regression algorithm, Gaussian Process Regression algorithm and scalable variational Gaussian process algorithm.

13. The method of claim 10, wherein the AI model is a deep learning algorithm model, and the deep learning algorithm model comprises a Convolutional Neural Network (CNN) algorithm model and a Mixture Density Neural Network (MDNN) algorithm model.

14. The method of claim 10, wherein the auxiliary training data is a first auxiliary training data, and the method further comprises:
generating a second auxiliary training data indicating whether at least one of the target die and the reference dies exists; and
training the AI model using the second auxiliary training data together with the main training data and the first auxiliary training data.

15. The method of claim 10, wherein the auxiliary training data further indicates whether the reference dies exist.

16. The method of claim 10, wherein the main training data and the auxiliary training data correspond to a combination of a temperature and a voltage.

17. The method of claim 10, wherein the main training data and the auxiliary training data correspond to a plurality of combinations of a plurality of temperatures and a plurality of voltages.

18. The method of claim 10, wherein the main training data and the auxiliary training data are a matrix or an array, and relative positions of a plurality of elements in the matrix or the array correspond to relative positions on the wafer of the target die and the reference dies.
